(19) United States
(12) Patent Application Publication
(10) Pub. No.: US 2026/0213525 A1
(43) Pub. Date: Jul. 23, 2026

(54) Server Information Handling System Overcurrent Protection System

(71) Applicant: Dell Products L.P., Round Rock, TX (US)

(72) Inventors: Timothy M. Lambert, Austin, TX (US); Puspa Kunwor, Round Rock, TX (US); Bates James Hunt, III, Round Rock, TX (US)

(21) Appl. No.: 19/032,806

(22) Filed: Jan. 21, 2025

(51) Int. Cl. H02H 9/02; H05K 7/14

(52) U.S. Cl. CPC H02H 9/02; H05K 7/1492

(57) ABSTRACT

An overcurrent system for use with an information handling system. The overcurrent system includes a system portion, the baseboard portion including a system power distribution element, the system power distribution element having an associated first power rating; a peripheral portion, the peripheral portion including a peripheral power distribution element, the peripheral power distribution element having an associated second power rating; and, an overcurrent protection circuit, the overcurrent protection circuit performing an overcurrent protection operation when the associated second power rating is greater than the associated first power rating.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a server type information handling system with an overcurrent protection system.

In one embodiment, the invention relates to an overcurrent system for use with an information handling system, comprising: a baseboard portion, the baseboard portion including a baseboard power distribution element, the baseboard power distribution element having an associated first power rating; a peripheral portion, the peripheral portion including a peripheral power distribution element, the peripheral power distribution element having an associated second power rating; and, an overcurrent protection circuit, the overcurrent protection circuit performing an overcurrent protection operation when the associated second power rating is greater than the associated first power rating.

In another embodiment, the invention relates to an overcurrent environment for an information handling system comprising: a baseboard, the baseboard including a baseboard power distribution element, the baseboard power distribution element having an associated first power rating; a peripheral component, the peripheral component including a peripheral power distribution element, the peripheral power distribution element having an associated second power rating; and, an overcurrent protection system, the overcurrent protection system performing an overcurrent protection operation when the associated second power rating is greater than the associated first power rating.

In another embodiment, the invention relates to a system comprising: a host; a baseboard coupled to the host, the baseboard including a baseboard power distribution element, the baseboard power distribution element having an associated first power rating; a peripheral component coupled to the baseboard, the peripheral component including a peripheral power distribution element, the peripheral power distribution element having an associated second power rating; and, an overcurrent protection system, the overcurrent protection system performing an overcurrent protection operation when the associated second power rating is greater than the associated first power rating.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIG. 4 shows a generalized schematic view of an overcurrent protection management system.

### DETAILED DESCRIPTION

Various aspects of the present disclosure include an appreciation that it is known to provide information handling systems with a plurality of components. Various aspects of the present disclosure include an appreciation that graphics processing unit (GPU) modules (often referred to as accelerator add in cards (AICs) are examples of components that are often included within an information handling system. Various aspects of the present disclosure include an appreciation that it may be desirable to provide an information handling system with an array of components. Various aspects of the present disclosure include an appreciation that it may be desirable to install an array of GPU modules within an information handling system.

Various aspects of the present disclosure include an appreciation that GPU modules are often configured to conform to standards. Various aspects of the present disclosure include an appreciation that the card electromechanical (CEM) standard is one such standard. Various aspects of the disclosure include an appreciation that it is known to provide information handling systems with control systems such as peripheral component interconnect express (PCIe) type control systems.

Various aspects of the present disclosure include an appreciation that certain standards have associated component power connection aspects. For example, a version of the PCIe CEM standard (e.g., PCIe CEM v. 6.0) supports 675 W power connections. Various aspects of the present disclosure include an appreciation that certain components can have power connections of 1000 W-1200 W by using multiple power connectors. Various aspects of the present disclosure include an appreciation that information handling system designs can support a substantial number of slots (e.g., 16 GPU slots and 8 general purpose CEM slots) which can result in information handling system power and cooling design challenges.

Various aspects of the present disclosure include an appreciation that it is known to use host processor modules (HPMs) and power distribution boards (PDBs) to deliver high power to subsystems such as CEM cards, accelerator trays, etc. Various aspects of the present disclosure include an appreciation that HPMs and PDBs have a variability of an amount of copper routed to each power tap that in most cases equals less than the connector rating. Various aspects of the present disclosure include an appreciation that this variability is often due to cost, other board routing needs, layer count/stackup, etc. (e.g., 600 W capable copper routed to an 864 W double Platform Infrastructure Connectivity Power (PICPWR) connector).

Various aspects of the present disclosure include an appreciation that it is known to use electronic fuse (efuse) on some peripheral components for one exact static/fixed trip level. Various aspects of the present disclosure include an appreciation that the static/fixed trip level may not be correct when coupled to a different source on a platform or on different platforms. Various aspects of the present disclosure include an appreciation that known efuses are not dynamic. Various aspects of the present disclosure include an appreciation that it is known to use an output current for a voltage output (IMON) signal to poll for thermal algorithm purposes.

Various aspects of the present disclosure include an appreciation that temperature sensors included within HPM or peripheral component circuit boards are often not accurate regarding temperatures of internal layers of the circuit boards. Various aspects of the present disclosure include an appreciation that temperature sensors included within HPM or peripheral component circuit boards are often not indicative of temperatures across the entire power path of the HPM or peripheral components.

Various aspects of the present disclosure include an appreciation that it would be desirable to provide an overcurrent protection system which can intelligently discover and change a trip point of a peripheral component. Various aspects of the present disclosure include an appreciation that it would be desirable to change the trip point of the peripheral component before aspects of the power transmission lines (e.g., a connector, a copper transmission line or wire) of the HPM or PDB exceeds predetermined limits. Various aspects of the present disclosure include an appreciation that it would be desirable to change the trip point which prevents a board malfunction due to excessive current.

A system and method are disclosed for providing a server type information handling system with an overcurrent protection system. In certain embodiments, the overcurrent protection system interacts with a baseboard management controller (BMC) of the information handling system.

In certain embodiments, the BMC performs a peripheral component discover operation. In certain embodiments, the peripheral component discovery operation discovers a device class of the peripheral component, a unique identifier (UID) attribute of the peripheral component, a host processor module type, a power distribution board type, or a combination thereof. In certain embodiments, the device class of the peripheral component, the UID attribute of the peripheral component, the host processor module type, the power distribution board type, or a combination thereof, are maintained as a priori knowledge (i.e., previously formed knowledge). In certain embodiments, the device class of the peripheral component, the UID attribute of the peripheral component, the host processor module type, the power distribution board type, or a combination thereof, are maintained within a power information table which is accessed by the BMC. In certain embodiments, the BMC obtains the information on a per PICPWR basis.

In certain embodiments, the BMC sets peripheral component IMON warning and critical thresholds. In certain embodiments, the peripheral component IMON warning and critical thresholds ensure that instantaneous spikes do not trip the overcurrent protection system.

In certain embodiments, the overcurrent protection system distinguishes between a critical overcurrent condition and a warning overcurrent condition. In certain embodiments, when a critical overcurrent condition is identified, the overcurrent protection system generates a power good (PG) fault. In certain embodiments, when a critical overcurrent condition is identified, the overcurrent protection system performs a field replaceable unit FRU isolation operation on the sourcing PICPWR and any associated subsystems. In certain embodiments, when a warning overcurrent condition is identified, the overcurrent protection system uses this system awareness to throttle or alter a workload executing on the peripheral component to avoid a threshold crossing condition.

In certain embodiments, the overcurrent protection system includes power good circuit which provides PG feedback and distinguishes between critical and warning conditions.

In certain embodiments, the BMC sets an IMON interrupt overcurrent critical threshold based on end-to-end power distribution least common denominator. In certain embodiments, the end-to-end power distribution includes power plane printed circuit board current carrying capabilities, along with connectors and cables along the path from source to load.

In certain embodiments, the overcurrent protection system links an IMON overcurrent critical indication with a peripheral component PowerGood indication. In certain embodiments, linking the IMON overcurrent critical indication with the peripheral component PowerGood indication results in consistent system power fault handling as a voltage out of range fault. In certain embodiments, the overcurrent protection system includes a bus hold circuit to provide power enable momentary enablement until local voltages are in range and no overcurrent is detected. In certain embodiments, the overcurrent protection system includes a bus hold feedback buffer via which overcurrent is detected. In certain embodiments, the overcurrent protection system includes a programmable gate array (PGA). In certain embodiments, the programmable gate array is configured to convert a power switch output signal (e.g., PWREN) into a PowerGood/output overcurrent input signal. In certain embodiments, the programmable gate array is configured to detect faults from the PowerGood/output overcurrent input signal. In certain embodiments, the programmable gate array detects faults on a falling edge of the power good/overcurrent input signal.

In certain embodiments, the BMC polls an IMON signal for output current early warnings. In certain embodiments, the overcurrent protection circuit adapt host workloads to attempt to avoid a critical event. In certain embodiments, the overcurrent protection circuit increases system cooling in an affected area. In certain embodiments, the overcurrent protection circuit increases system cooling in an affected area because even if power exceeds a warning threshold damage may be avoided if the area is sufficiently cooled. In certain embodiments, the overcurrent protection circuit can throttle or alter a maximum permitted power draw of a peripheral component. In certain embodiments, the overcurrent protection circuit can throttle or alter a maximum permitted power draw via a PCI Express configuration space of the peripheral component.

In certain embodiments, upon detection of an Iout overcurrent critical event, the BMC may implement alternate slot power limits. In certain embodiments, the alternate slot power limits may be implemented at a next subsequent boot. In certain embodiments, the alternate slot power limits can be below that granted by form factor or PCIe CEM AUX Cable sense lines. In certain embodiments, the BMC lower the slot power limit via slot priority, by evenly dividing the needed peak power reduction by a number of slots/devices on the offending overall peripheral component, or a combination thereof.

In certain embodiments, the overcurrent protection system advantageously provides granular and effective overcurrent protection. In certain embodiments, the overcurrent protection circuit advantageously provides granular and effective overcurrent protection for a system containing an array of components. In certain embodiments, the overcurrent protection system advantageously provides direct power plane temperature measurements.

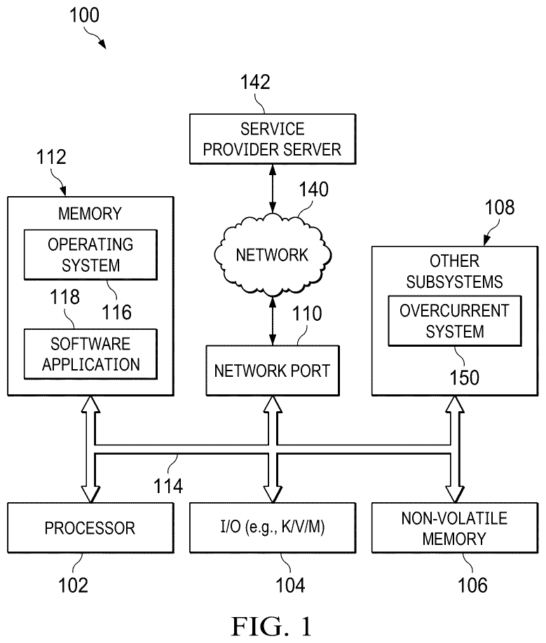

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include an overcurrent system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the overcurrent system 150 includes an overcurrent protection system and a plurality of components coupled to the overcurrent protection system. In certain embodiments, the plurality of components are arranged as an array of components. In certain embodiments, the plurality of components include a plurality of GPUs. In certain embodiments, the plurality of GPUs are designed to support artificial intelligence (AI) workloads.

In certain embodiments, the overcurrent system 150 includes an overcurrent protection system. In certain embodiments, the overcurrent protection system interacts with, includes, or a combination thereof, a baseboard management controller (BMC) of the information handling system. In certain embodiments, the overcurrent system 150 includes an overcurrent protection circuit. In certain embodiments, the overcurrent protection circuit performs an overcurrent protection operation. As used herein, an overcurrent protection operation broadly refers to any function, task, procedure, or process performed, directly or indirectly, within an information handling system to manage current within the information handling system when a peripheral component power rating is greater than a baseboard power rating. In certain embodiments, managing the current within the information handling system includes intelligently discovering current issues, changing a current detection trip point of a peripheral component, or a combination thereof.

In certain embodiments, the BMC performs a peripheral component discovery operation. In certain embodiments, the peripheral component discovery operation discovers a device class of the peripheral component, a unique identifier (UID) attribute of the peripheral component, a host processor module type, a power distribution board type, or a combination thereof. In certain embodiments, the device class of the peripheral component, the UID attribute of the peripheral component, the host processor module type, the power distribution board type, or a combination thereof, are maintained as a priori knowledge (i.e., previously formed knowledge). In certain embodiments, the device class of the peripheral component, the UID attribute of the peripheral component, the host processor module type, the power distribution board type, or a combination thereof, are maintained within a power information table which is accessed by the BMC. In certain embodiments, the BMC obtains the information on a per PICPWR basis.

In certain embodiments, the BMC sets peripheral component IMON warning and critical thresholds. In certain embodiments, the peripheral component IMON warning and critical thresholds ensure that instantaneous spikes do not trip the overcurrent protection system.

In certain embodiments, the overcurrent protection system distinguishes between a critical overcurrent condition and a warning overcurrent condition. In certain embodiments, when a critical overcurrent condition is identified, the overcurrent protection system generates a power good (PG) fault. In certain embodiments, when a critical overcurrent condition is identified, the overcurrent protection system performs a field replaceable unit FRU isolation operation on the sourcing PICPWR and any associated subsystems. In certain embodiments, when a warning overcurrent condition is identified, the overcurrent protection system uses this system awareness to throttle or alter a workload executing on the peripheral component to avoid a threshold crossing condition.

In certain embodiments, the overcurrent protection system includes power good circuit which provides power good feedback and distinguishes between critical and warning conditions.

In certain embodiments, the BMC sets an IMON interrupt overcurrent critical threshold based on end-to-end power distribution least common denominator. In certain embodiments, the end-to-end power distribution includes power plane printed circuit board current carrying capabilities, along with connectors and cables along the path from source to load.

In certain embodiments, the overcurrent protection system links an IMON overcurrent critical indication with a peripheral component PowerGood indication. In certain embodiments, linking the IMON overcurrent critical indication with the peripheral component PowerGood indication results in consistent system power fault handling as a voltage out of range fault. In certain embodiments, the overcurrent protection system includes a bus hold circuit to provide power enable momentary enablement until local voltages are in range and no overcurrent is detected. In certain embodiments, the overcurrent protection system includes a bus hold feedback buffer via which overcurrent is detected. In certain embodiments, the overcurrent protection system includes a programmable gate array (PGA). In certain embodiments, the programmable gate array is configured to convert a power switch output signal (e.g., PWREN) into a PowerGood/output overcurrent input signal. In certain embodiments, the programmable gate array is configured to detect faults from the PowerGood/output overcurrent input signal. In certain embodiments, the programmable gate array detects faults on a falling edge of the PowerGood/overcurrent input signal.

In certain embodiments, the BMC polls an IMON signal for output current early warnings. In certain embodiments, the overcurrent protection circuit adapt host workloads to attempt to avoid a critical event. In certain embodiments, the overcurrent protection circuit increases system cooling in an affected area. In certain embodiments, the overcurrent protection circuit increases system cooling in an affected area because even if power exceeds a warning threshold damage may be avoided if the area is sufficiently cooled. In certain embodiments, the overcurrent protection circuit can throttle or alter a maximum permitted power draw of a peripheral component. In certain embodiments, the overcurrent protection circuit can throttle or alter a maximum permitted power draw via a PCI Express configuration space of the peripheral component.

In certain embodiments, upon detection of an Iout overcurrent critical event, the BMC may implement alternate slot power limits. In certain embodiments, the alternate slot power limits may be implemented at a next subsequent boot. In certain embodiments, the alternate slot power limits can be below that granted by form factor or PCIe CEM AUX Cable sense lines. In certain embodiments, the BMC lowers the slot power limit via slot priority, by evenly dividing the needed peak power reduction by a number of slots/devices on the offending overall peripheral component, or a combination thereof.

In certain embodiments, the overcurrent protection system advantageously provides granular and effective overcurrent protection. In certain embodiments, the overcurrent protection circuit advantageously provides granular and effective overcurrent protection for a system containing an array of components. In certain embodiments, the overcurrent protection system advantageously provides direct power plane temperature measurements.

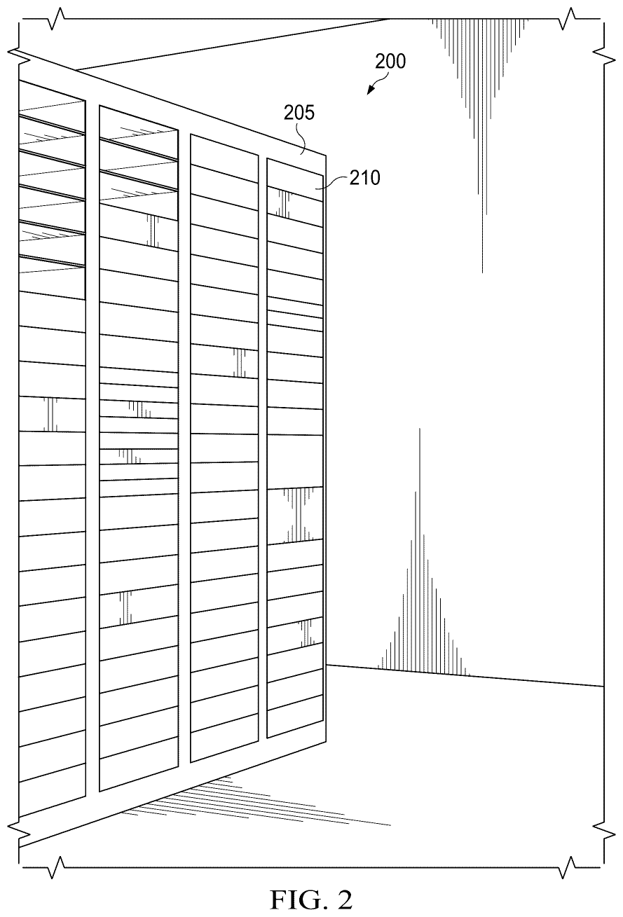

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100, as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit, and a 4U rack unit. In general, a 1U rack unit is substantially (i.e., +/−20%) 1.75″ high, a 2U rack unit is substantially (i.e., +/−20%) 3.5″ high, and a 4U rack height is substantially (i.e., +/−20%) 7.0″ high.

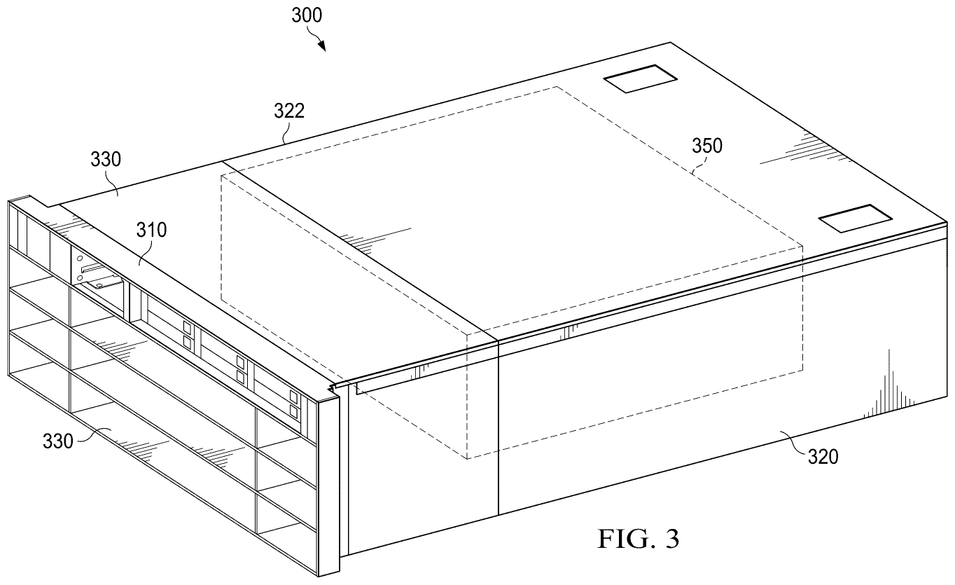

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the server system 300 includes an overcurrent environment 350. In certain embodiments, the overcurrent environment 350 corresponds to overcurrent system 150.

In certain embodiments, the overcurrent environment 350 includes an overcurrent management system and a plurality of components coupled to the overcurrent management system. In certain embodiments, the plurality of components are arranged as an array of components. In certain embodiments, the plurality of components include a plurality of GPUs. In certain embodiments, the plurality of GPUs are designed to support artificial intelligence (AI) workloads.

In certain embodiments, the overcurrent environment 350 includes an overcurrent protection system and a plurality of components coupled to the overcurrent protection system. In certain embodiments, the plurality of components are arranged as an array of components. In certain embodiments, the plurality of components include a plurality of GPUs. In certain embodiments, the plurality of GPUs are designed to support artificial intelligence (AI) workloads.

In certain embodiments, the overcurrent system includes an overcurrent protection system. In certain embodiments, the overcurrent protection system interacts with, includes, or a combination thereof, a baseboard management controller (BMC) of the information handling system.

In certain embodiments, the BMC performs a peripheral component discover operation. In certain embodiments, the peripheral component discovery operation discovers a device class of the peripheral component, a unique identifier (UID) attribute of the peripheral component, a host processor module type, a power distribution board type, or a combination thereof. In certain embodiments, the device class of the peripheral component, the UID attribute of the peripheral component, the host processor module type, the power distribution board type, or a combination thereof, are maintained as a priori knowledge (i.e., previously formed knowledge). In certain embodiments, the device class of the peripheral component, the UID attribute of the peripheral component, the host processor module type, the power distribution board type, or a combination thereof, are maintained within a power information table which is accessed by the BMC. In certain embodiments, the BMC obtains the information on a per PICPWR basis.

In certain embodiments, the BMC sets peripheral component IMON warning and critical thresholds. In certain embodiments, the peripheral component IMON warning and critical thresholds ensure that instantaneous spikes do not trip the overcurrent protection system.

In certain embodiments, the overcurrent protection system distinguishes between a critical overcurrent condition and a warning overcurrent condition. In certain embodiments, when a critical overcurrent condition is identified, the overcurrent protection system generates a power good (PG) fault. In certain embodiments, when a critical overcurrent condition is identified, the overcurrent protection system performs a field replaceable unit FRU isolation operation on the sourcing PICPWR and any associated subsystems. In certain embodiments, when a warning overcurrent condition is identified, the overcurrent protection system uses this system awareness to throttle or alter a workload executing on the peripheral component to avoid a threshold crossing condition.

In certain embodiments, the overcurrent protection system includes a power good circuit which provides power good feedback and distinguishes between critical and warning conditions.

In certain embodiments, the BMC sets an IMON interrupt overcurrent critical threshold based on end-to-end power distribution least common denominator. In certain embodiments, the end-to-end power distribution includes power plane printed circuit board current carrying capabilities, along with connectors and cables along the path from source to load.

In certain embodiments, the overcurrent protection system links an IMON overcurrent critical indication with a peripheral component PowerGood indication. In certain embodiments, linking the IMON overcurrent critical indication with the peripheral component PowerGood indication results in consistent system power fault handling as a voltage out of range fault. In certain embodiments, the overcurrent protection system includes a bus hold circuit to provide power enable momentary enablement until local voltages are in range and no overcurrent is detected. In certain embodiments, the overcurrent protection system includes a bus hold feedback buffer via which overcurrent is detected. In certain embodiments, the overcurrent protection system includes a programmable gate array (PGA). In certain embodiments, the programmable gate array is configured to convert a power switch output signal (e.g., PWREN) into a PowerGood/output overcurrent input signal. In certain embodiments, the programmable gate array is configured to detect faults from the PowerGood/output overcurrent input signal. In certain embodiments, the programmable gate array detects faults on a falling edge of the power good/overcurrent input signal.

In certain embodiments, the BMC polls an IMON signal for output current early warnings. In certain embodiments, the overcurrent protection circuit adapt host workloads to attempt to avoid a critical event. In certain embodiments, the overcurrent protection circuit increases system cooling in an affected area. In certain embodiments, the overcurrent protection circuit increases system cooling in an affected area because even if power exceeds a warning threshold damage may be avoided if the area is sufficiently cooled. In certain embodiments, the overcurrent protection circuit can throttle or alter a maximum permitted power draw of a peripheral component. In certain embodiments, the overcurrent protection circuit can throttle or alter a maximum permitted power draw via a PCI Express configuration space of the peripheral component.

In certain embodiments, upon detection of an Iout overcurrent critical event, the BMC may implement alternate slot power limits. In certain embodiments, the alternate slot power limits may be implemented at a next subsequent boot. In certain embodiments, the alternate slot power limits can be below that granted by form factor or PCIe CEM AUX Cable sense lines. In certain embodiments, the BMC lowers the slot power limit via slot priority, by evenly dividing the needed peak power reduction by a number of slots/devices on the offending overall peripheral component, or a combination thereof.

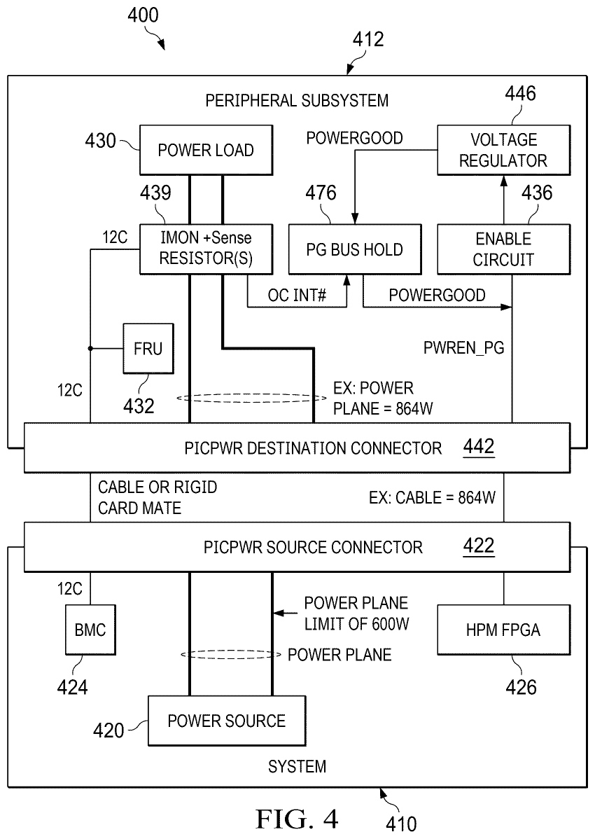

FIG. 4 shows a generalized schematic view of an overcurrent protection system 400. In certain embodiments, the overcurrent protection system 400 corresponds to overcurrent system 150. In certain embodiments, the overcurrent protection system 400 includes a system portion 410, a peripheral portion 412, or a combination thereof. In certain embodiments, the system portion 410 includes one or more of a motherboard, a planar board, a host processor module, a baseboard, or a combination thereof.

In certain embodiments, the system portion 410 includes a power source 420, a source connector 422, a BMC 424, an overcurrent circuit 426 (such as a HPM overcurrent circuit), or a combination thereof. In certain embodiments, the power source 420 is electrically coupled to the source connector 422. In certain embodiments, the source connector 422 includes a power source connector. In certain embodiments, the power source connector includes a PICPWR power source connector. In certain embodiments, the power source 420 is electrically coupled to the source connector 422 via a system board power distribution component. In certain embodiments, the system board power distribution component has an associated first power rating.

In certain embodiments, the BMC 424 is coupled to the source connector 422. In certain embodiments, the BMC 424 is coupled to the source connector 422 via a serial communication bus. In certain embodiments, the serial communication bus includes an Inter-Integrated circuit (I2C) signal line. In certain embodiments, the HPM overcurrent circuit 426 is coupled to the source connector 422. In certain embodiments, the HPM overcurrent circuit 426 is coupled to the source connector 422 via a signal line. In certain embodiments, the signal line includes power good power enable (PWREN_PG) signal line. In certain embodiments, the HPM overcurrent circuit 426 includes a programmable gate array.

In certain embodiments, the system portion 410 is configured as a printed circuit board. In certain embodiments, the printed circuit board includes a system board power plane. In certain embodiments, the system board power plane corresponds to the system board power distribution component. In certain embodiments, the system board power plane has an associated first power rating. In certain embodiments, the associated first power rating is substantially (i.e., +/−20%) 600 Watts. In certain embodiments, the power source 420 and the source connector 422 are electrically coupled via the system board power plane.

In certain embodiments, the peripheral portion 412 includes a power load 430, a field replaceable unit (FRU) 432, a sense circuit 434, a bus hold component 436, an enable circuit 438, a voltage regulator component 440, a destination connector 442, or a combination thereof.

In certain embodiments, the power load 430 is electrically coupled to the destination connector 442. In certain embodiments, the destination connector 442 includes a power destination connector. In certain embodiments, the power destination connector includes a PICPWR power destination connector. In certain embodiments, the power load 430 is electrically coupled to the destination connector 442 via a peripheral power distribution component. In certain embodiments, the peripheral power distribution component has an associated second power rating.

In certain embodiments, the FRU 432 describes one or more peripheral power distribution attributes. In certain embodiments, the FRU 432 is coupled to the destination connector 442. In certain embodiments, the FRU 432 is coupled to the destination connector 442 via a serial communication bus. In certain embodiments, the serial communication bus includes an Inter-Integrated circuit (I2C) signal line. In certain embodiments, the sense circuit 434 includes an IMON signal detector and at least one sense resistor. In certain embodiments, the sense circuit 434 is coupled to the destination connector 442. In certain embodiments, the sense circuit 434 is coupled to the destination connector 442 via a serial communication bus. In certain embodiments, the serial communication bus includes an Inter-Integrated circuit (I2C) signal line. In certain embodiments, the FRU 432 is coupled to the sense circuit 434. In certain embodiments, the FRU 432 is coupled to the sense circuit 434 via a serial communication bus. In certain embodiments, the serial communication bus includes an Inter-Integrated circuit (I2C) signal line.

In certain embodiments, the sense circuit 434 is coupled to the power load 430. In certain embodiments, the sense circuit 434 is coupled to the destination power distribution element. In certain embodiments, the sense circuit 434 is coupled to the power load 430 via the destination power distribution element. In certain embodiments, the sense circuit 430 is coupled to the bus hold component 436. In certain embodiments, the bus hold component 436 includes a power good bus hold component. In certain embodiments, the sense circuit 430 is coupled to the bus hold component 436 via a signal line. In certain embodiments, the signal line includes an interrupt (OC INT #) signal line. In certain embodiments, the bus hold component 436 is coupled to the enable circuit 438. In certain embodiments, the bus hold component 436 is coupled to the enable circuit 438 via a signal line. In certain embodiments, the signal line includes power good (PowerGood) signal line. In certain embodiments, the bus hold component 436, the enable circuit 438, or a combination thereof, are coupled to the voltage regulator component 440. In certain embodiments, the enable circuit 438 is coupled to the destination connector 442 via a signal line. In certain embodiments, the signal line includes power good power enable (PWREN_PG) signal line.

In certain embodiments, the peripheral portion 412 is configured as a printed circuit board. In certain embodiments, the printed circuit board includes a peripheral board power plane. In certain embodiments, the peripheral board power plane corresponds to the peripheral power distribution component. In certain embodiments, the peripheral board power plane has an associated second power rating. In certain embodiments, the associated second power rating is greater than the associated first power rating. In certain embodiments, the associated second power rating is substantially (i.e., +/−20%) 864 Watts. In certain embodiments, the power load 430 and the destination connector 432 are electrically coupled via the peripheral board power plane.

In certain embodiments, the source connector 422 and the destination connector 442 are coupled. In certain embodiments, the source connector 422 and the destination connector 442 are coupled via a cable, a rigid card mate, or a combination thereof. In certain embodiments, the cable, the rigid card mate, or the combination thereof have a power distribution rating. In certain embodiments, the power distribution rating corresponds to the second power rating of the peripheral board power distribution element.

In certain embodiments, the overcurrent protection system 400 limits a load of a weakest link to a predetermined power threshold. In certain embodiments, the predetermined power threshold is substantially (i.e., +/−20%) 600 W. In certain embodiments, the overcurrent protection system 400 denies power to the subsystem having the weakest link. In certain embodiments, the weakest link may be any board, connector or conductor along a path which exceeds the predetermined power threshold. In certain embodiments, the overcurrent protection system 400 identifies corresponding attributes of the peripheral component when performing a maximum allowed power calculation. Reactions to detection of an overcurrent condition can include denial of power enablement; throttling or overcurrent limiting of enable power, component area cooling, or a combination thereof.

In certain embodiments, the BMC 424 performs a peripheral component discover operation. In certain embodiments, the peripheral portion 412 includes a peripheral component. In certain embodiments, the peripheral component discovery operation discovers a device class of the peripheral component, a unique identifier (UID) attribute of the peripheral component, a host processor module type, a power distribution board type, or a combination thereof. In certain embodiments, the device class of the peripheral component, the UID attribute of the peripheral component, the host processor module type, the power distribution board type, or a combination thereof, are maintained as a priori knowledge (i.e., previously formed knowledge). In certain embodiments, the device class of the peripheral component, the UID attribute of the peripheral component, the host processor module type, the power distribution board type, or a combination thereof, are maintained within a power information table which is accessed by the BMC 424. In certain embodiments, the BMC 424 obtains the information on a per PICPWR basis.

In certain embodiments, the BMC 424 sets peripheral component IMON warning and critical thresholds. In certain embodiments, the IMON warning and critical thresholds are provided to the FRU 432, the sense circuit 434, or a combination thereof. In certain embodiments, the peripheral component IMON warning and critical thresholds ensure that instantaneous spikes do not trip the overcurrent protection system.

In certain embodiments, the overcurrent protection system distinguishes between a critical overcurrent condition and a warning overcurrent condition. In certain embodiments, when a critical overcurrent condition is identified, the overcurrent protection system generates a power good (PG) fault. In certain embodiments, the sense circuit 434 generates the PG fault. In certain embodiments, the PG fault is provided to the bus hold component 436. In certain embodiments, when a critical overcurrent condition is identified, the overcurrent protection system performs a field replaceable unit FRU isolation operation on the sourcing PICPWR and any associated subsystems. In certain embodiments, when a warning overcurrent condition is identified, the overcurrent protection system uses this system awareness to throttle or alter a workload executing on the peripheral component to avoid a threshold crossing condition.

In certain embodiments, the overcurrent protection system includes a power good circuit which provides power good feedback and distinguishes between critical and warning conditions. In certain embodiments, the enable circuit 438 includes the power good circuit.

In certain embodiments, the BMC 424 sets an IMON interrupt overcurrent critical threshold based on end-to-end power distribution least common denominator. In certain embodiments, the end-to-end power distribution includes power plane printed circuit board current carrying capabilities, along with connectors and cables along the path from source to load.

In certain embodiments, the overcurrent protection system links an IMON overcurrent critical indication with a peripheral component PowerGood indication. In certain embodiments, linking the IMON overcurrent critical indication with the peripheral component PowerGood indication results in consistent system power fault handling as a voltage out of range fault. In certain embodiments, the overcurrent protection system includes a bus hold circuit to provide power enable momentary enablement until local voltages are in range and no overcurrent is detected. In certain embodiments, the overcurrent protection system includes a bus hold feedback buffer via which overcurrent is detected. In certain embodiments, the overcurrent protection system includes a programmable gate array (PGA). In certain embodiments, the bus hold component 436 includes the programmable gate array. In certain embodiments, the programmable gate array is configured to convert a power switch output signal (e.g., PWREN) into a PowerGood/output overcurrent input signal. In certain embodiments, the programmable gate array is configured to detect faults from the PowerGood/output overcurrent input signal. In certain embodiments, the programmable gate array detects faults on a falling edge of the power good/overcurrent input signal.

In certain embodiments, the BMC 424 polls an IMON signal for output current early warnings. In certain embodiments, the overcurrent protection circuit adapts host workloads to attempt to avoid a critical event. In certain embodiments, the overcurrent protection circuit increases system cooling in an affected area. In certain embodiments, the overcurrent protection circuit increases system cooling in an affected area because even if power exceeds a warning threshold damage may be avoided if the area is sufficiently cooled. In certain embodiments, the overcurrent protection circuit can throttle or alter a maximum permitted power draw of a peripheral component. In certain embodiments, the overcurrent protection circuit can throttle or alter a maximum permitted power draw via a PCI Express configuration space of the peripheral component.

In certain embodiments, upon detection of an Iout overcurrent critical event, the BMC 424 may implement alternate slot power limits. In certain embodiments, the alternate slot power limits may be implemented at a next subsequent boot. In certain embodiments, the alternate slot power limits can be below that granted by form factor or PCIe CEM AUX Cable sense lines. In certain embodiments, the BMC 424 lowers the slot power limit via slot priority, by evenly dividing the needed peak power reduction by a number of slots/devices on the offending overall peripheral component, or a combination thereof.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. An overcurrent system for use with an information handling system, comprising:
a system portion, the system portion including a system power distribution element, the system power distribution element having an associated first power rating;
a peripheral portion, the peripheral portion including a peripheral power distribution element, the peripheral power distribution element having an associated second power rating; and,
an overcurrent protection circuit, the overcurrent protection circuit performing an overcurrent protection operation when the associated second power rating is greater than the associated first power rating.

2. The overcurrent system of claim 1, wherein:
the overcurrent protection circuit includes a baseboard management controller (BMC); and,
the BMC performs, at least in part, the overcurrent protection operation.

3. The overcurrent system of claim 2, wherein:
the BMC sets an IMON interrupt overcurrent threshold when performing the overcurrent protection operation.

4. The overcurrent system of claim 2, wherein:
the BMC sets a peripheral component IMON warning threshold and a peripheral component IMON critical threshold; and,
the overcurrent protection circuit distinguishes between a warning overcurrent condition and a critical overcurrent condition based upon the peripheral component IMON warning threshold and the peripheral component IMON critical threshold.

5. The overcurrent system of claim 1, wherein:
the overcurrent protection circuit includes a hold circuit, the hold circuit generating a power fault when a power threshold is exceeded.

6. The overcurrent system of claim 5, wherein:
the hold circuit includes an overcurrent circuit, the overcurrent circuit being configured to convert a power switch output signal into a PowerGood/output overcurrent input signal.

7. An overcurrent environment for an information handling system comprising:
a system board, the system board including a system board power distribution element, the system board power distribution element having an associated first power rating;
a peripheral component, the peripheral component including a peripheral power distribution element, the peripheral power distribution element having an associated second power rating; and,
an overcurrent protection system, the overcurrent protection system performing an overcurrent protection operation when the associated second power rating is greater than the associated first power rating.

8. The overcurrent environment of claim 7, wherein:
the overcurrent protection system includes a baseboard management controller (BMC); and,
the BMC performs, at least in part, the overcurrent protection operation.

9. The overcurrent environment of claim 8, wherein:
the BMC sets an IMON interrupt overcurrent threshold when performing the overcurrent protection operation.

10. The overcurrent environment of claim 8, wherein:
the BMC sets a peripheral component IMON warning threshold and a peripheral component IMON critical threshold; and,
the overcurrent protection circuit distinguishes between a warning overcurrent condition and a critical overcurrent condition based upon the peripheral component IMON warning threshold and the peripheral component IMON critical threshold.

11. The overcurrent environment of claim 7, wherein:
the overcurrent protection system includes a hold circuit, the hold circuit generating a power fault when a power threshold is exceeded.

12. The overcurrent environment of claim 11, wherein:
the hold circuit includes an overcurrent circuit, the overcurrent circuit being configured to convert a power switch output signal into a PowerGood/output overcurrent input signal.

13. A system comprising:
a host;
a system board coupled to the host, the system board including a system board power distribution element, the system board power distribution element having an associated first power rating;
a peripheral component coupled to the baseboard, the peripheral component including a peripheral power distribution element, the peripheral power distribution element having an associated second power rating; and,
an overcurrent protection system, the overcurrent protection system performing an overcurrent protection operation when the associated second power rating is greater than the associated first power rating.

14. The system of claim 13, wherein:
the system includes a baseboard management controller (BMC); and,
the BMC performs, at least in part, the overcurrent protection operation.

15. The system of claim 14, wherein:
the BMC sets an IMON interrupt overcurrent threshold when performing the overcurrent protection operation.

16. The system of claim 14, wherein:
the BMC sets a peripheral component IMON warning threshold and a peripheral component IMON critical threshold; and,
the overcurrent protection circuit distinguishes between a warning overcurrent condition and a critical overcurrent condition based upon the peripheral component IMON warning threshold and the peripheral component IMON critical threshold.

17. The system of claim 13, wherein:
the overcurrent protection system includes a hold circuit, the hold circuit generating a power fault when a power threshold is exceeded.

18. The system of claim 17, wherein:
the hold circuit includes an overcurrent circuit, the overcurrent circuit being configured to convert a power switch output signal into a PowerGood/output overcurrent input signal.
